(19) United States
(12) Patent Application Publication
(10) Pub. No.: US 2026/0299443 A1
(43) Pub. Date: Oct. 1, 2026

(54) LITHOGRAPHY TOOL AND METHOD THEREOF

(71) Applicants: TSMC CHINA COMPANY LIMITED, Shanghai (CN); TAIWAN SEMICONDUCTOR MANUFACTURING COMPANY, LTD., Hsinchu (TW)

(72) Inventors: Feihu WANG, Shanghai City (CN); Jie LIU, Shanghai City (CN); Lei WANG, Shanghai City (CN)

(73) Assignees: TSMC CHINA COMPANY LIMITED, Shanghai (CN); TAIWAN SEMICONDUCTOR MANUFACTURING COMPANY, LTD., Hsinchu (TW)

(21) Appl. No.: 19/178,045

(22) Filed: Apr. 14, 2025

(30) Foreign Application Priority Data
Mar. 26, 2025 (CN) 202520552842.1

(51) Int. Cl. G03F 7/00; G02B 7/02

(52) U.S. Cl. CPC G03F 7/70975; G02B 7/02; G03F 7/70066

(57) ABSTRACT

A method includes fixing a supporting bracket to a working table in a lithography tool; placing a lifting device on the supporting bracket; lifting an optical element in lithography tool, using the lifting device, from a first level to a second level higher than the first level; rotating the optical element through a shaft connected with the optical element; and repairing the optical element.

### PRIORITY CLAIM AND CROSS-REFERENCE

The present application claims priority to China Application Serial Number 202520552842.1, filed Mar. 26, 2025, which is herein incorporated by reference.

### BACKGROUND

In semiconductor manufacturing, lithography tools are used to apply patterns onto substrates by selectively exposing photoresist layers on the substrates to a radiation beam. Optical lenses are used in a lithography apparatus to direct the radiation beam from a radiation source to the substrate being processed. Optical lenses in lithography tools are made of fine quality materials and need to be replaced regularly because of contamination acquired during operation.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography tool in accordance with some embodiments.

FIGS. 2A and 2B are schematic views of a lifting device in accordance with some embodiments.

FIGS. 3A, 3B, 3C, and 3D are schematic views of a supporting bracket in accordance with some embodiments.

FIGS. 4A and 4B are schematic views of a rotation assisting tool in accordance with some embodiments.

FIG. 5 is a method of operating a lithography tool in accordance with some embodiments.

FIGS. 6 to 11 are schematic views of a lithography tool at various stages of operating a lithography tool in accordance with some embodiments.

FIGS. 12A and 12B are schematic views of a lifting device in accordance with some embodiments.

FIG. 13 is a schematic view of a supporting bracket in accordance with some embodiments.

FIGS. 14A and 14B are schematic views of a rotation assisting tool in accordance with some embodiments.

FIG. 15 is a method of operating a lithography tool in accordance with some embodiments.

FIGS. 16 to 21 are schematic views of a lithography tool at various stages of operating a lithography tool in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

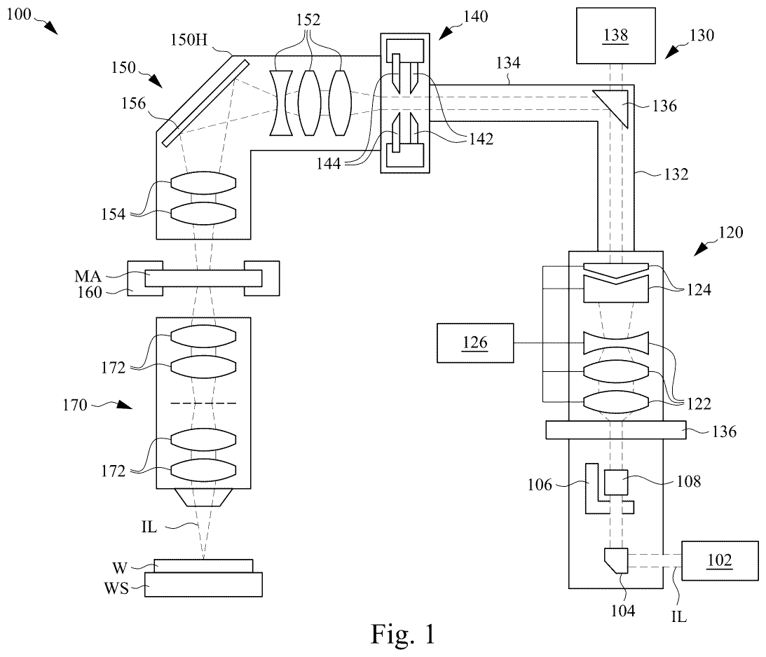

FIG. 1 is a schematic view of a lithography tool in accordance with some embodiments. Shown there is a lithography tool 100. The lithography tool 100 may include an alignment and exposure tool, also known as a stepper and a scanner, configured to transfer circuit design patterns to a light sensitive layer on a substrate. The lithography tool 100 may be an ultra violet (UV) lithography tool, a deep ultra violet (DUV) lithography tool, an immersion lithography tool, an extreme ultra violet (EUV) lithography tool, an electron beam lithography tool, an x-ray lithography tool, an ion projection lithography tool, or any suitable exposure tools using laser radiation source to generate a radiation beam for exposure.

The lithography tool 100 includes a light source 102. In some embodiments, the light source 102 may be an ArF excimer laser light source (oscillation wavelength 193 nm). As the exposure light source, lasers which emit laser light in the ultraviolet range in the oscillation step, such as a KrF excimer laser (wavelength 248 nm) or an F₂ laser (wavelength 157 nm), or devices emitting high-harmonic laser light substantially in the vacuum ultraviolet range, obtained by wavelength conversion of near-infrared laser light from a solid state laser light source (YAG laser, semiconductor laser, or similar), as well as a mercury discharge lamp often used in exposure equipment of this kind, or similar can be used.

In FIG. 1, a radiation beam IL is generated by the light source 102. The radiation beam IL passes through a beam steering system 104. In some embodiments, the beam steering system 104 may include one or more steering mirrors, so as to adjust the propagation direction of the radiation beam IL.

The beam steering system 104 directs the radiation beam IL to a beam-matching unit (BMU) 106, which includes a movable mirror or similar, in order to match the beam to the position of the optical path with the projection exposure apparatus body. A variable attenuator 108 is provided adjacent to the BMU 106. In some embodiments, the variable attenuator 108 is configured to adjust the average energy of each pulse beam of the radiation beam IL. For example, a plurality of optical filters that have different beam attenuating ratios being arranged so that they can be switched to change the beam attenuating ratio in sequence can be used.

The lithography tool 100 further includes a shutter system 110 positioned at the downstream of the BMU 106 and optically coupled with the BMU 106. In some embodiments, the shutter system 110 may include at least one shutter. For example, two shutters are provided to control the output of the radiation beam IL. A safety shutter held open by a coil and arranged to close automatically if any of the panels of a casing of the lithographic apparatus are opened. A rotary shutter is driven by a motor for each exposure.

The lithography tool 100 further includes a zoom-axicon optic system 120 positioned at the downstream of the shutter system 110 and optically coupled with the shutter system 110. The zoom-axicon optic system 120 includes a set of zoom lenses 122 and an axicon 124, which are driven by a motor drive 126. Here, two convex lenses are illustrated as an example of the zoom lenses 122. However, it is understood that this is merely used to explain, it will be appreciated that the zoom lenses 122 may include several lenses, including a combination of convex lenses and/or concave lenses. The zoom lenses 122 are arranged to determine the size of the beam or the outer radius of an annular illumination mode. The set of zoom lenses 122 can be collectively referred to as a zoom lens system.

The axicon 124 includes a concave conical lens and complementary convex conical lens whose separation is adjustable by the motor drive 126. The distance between the two elements of the axicon 124 may be adjusted by moving one of the elements along the direction of the optical axis. This allows the annularity of the radiation beam IL to be adjusted. When the axicon 124 is closed, i.e. the gap between the conical faces is zero, the radiation beam IL may have a disk shape. When a gap is present between the conical faces of the axicon 124, an annular intensity distribution may result, the inner radial extent of the annulus being determined by the distance between the two conical faces.

In the embodiments of FIG. 1, the set of zoom lenses 122 is positioned between the axicon 124 and the light source 102 along the optical path of the radiation beam IL. However, the relative position between the set of zoom lenses 122 and the axicon 124 can be exchanged. For example, in other embodiments, the axicon 124 is positioned between the set of zoom lenses 122 and the light source 102 along the optical path of the radiation beam IL.

The lithography tool 100 further includes an integrator 130 positioned at the downstream of the zoom-axicon optic system 120 and optically coupled to the zoom-axicon optic system 120. In some embodiments, the integrator 130 includes two elongate quartz rods 132 and 134 joined at a right-angle prism 136, the hypotenuse surface of which is partially silvered to allow a small, known proportion of the beam energy through to an energy sensor 138. The radiation beam IL undergoes multiple internal reflections in the quartz rods 132 and 134 so that, looking back through it, there is seen a plurality of spaced apart virtual sources, thus evening out the intensity distribution of the radiation beam IL. The function of the integrator is to improve the homogeneity of the spatial and/or angular intensity distribution of the radiation beam IL.

The lithography tool 100 further includes a reticle blind mechanism 140 at the downstream of the integrator 130 and optically coupled to the integrator 130. In some embodiments, the reticle blind mechanism 140 may include a fixed blind unit 142 and a movable blind unit 144 arranged near the fixed blind unit 142. The fixed blind unit 142 may include blades forming a fixed aperture. The movable blind unit 144 may include movable blades with an adjustable aperture. The arrangement surface of the movable blades that make up the movable blind unit 144 is conjugate to the pattern surface of a reticle (e.g., reticle MA). By using the fixed blind unit 142 and the movable blind unit 144, a slit-shaped illumination area through which a reticle (e.g., reticle MA) is illuminated, can be set at a rectangular shape of a preferred size and form.

The lithography tool 100 further includes a reticle masking (REMA) imaging optic system 150 at the downstream of the reticle blind mechanism 140 and optically coupled to the reticle blind mechanism 140. The REMA imaging optic system 150 includes a housing 150H. In some embodiments, inside the housing 150H, air (oxygen) concentration does not exceed a few percent, and the housing 150H may be filled with clean dry nitrogen gas (N₂), a helium gas (He), and/or other inert gas having an air (oxygen) concentration less than about 1%. The REMA imaging optic system 150 includes a first set of condenser lenses 152 and a second set of condenser lenses 154, in which the first set of condenser lenses 152 and the second set of condenser lenses 154 are optically coupled with each other through a mirror 156. In some embodiments, the first set of condenser lenses 152 may include one or more lenses, and the present disclosure is not limited thereto. Similarly, the second set of condenser lenses 154 may include one or more lenses.

The lithography tool 100 further includes a reticle MA at the downstream of the REMA imaging optic system 150 and optically coupled to the REMA imaging optic system 150. The reticle MA is heled by a reticle stage 160. The radiation beam IL passes through the first set of condenser lenses 152, the mirror 156 to bend the optical path, and the second set of condenser lenses 154, and illuminates an illumination area in the circuit pattern area of the reticle MA. On the reticle stage 160, the reticle MA is fixed, for example, by vacuum chucking. The reticle stage 160 is structured, so that it can be finely driven two-dimensionally within a plane perpendicular to the optical axis of the radiation beam IL to perform positioning of the reticle MA.

The term “reticle” used herein should be broadly interpreted as referring to any device that can be used to impart a radiation beam with a pattern such as to create a pattern in a target portion of the wafer. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit. In some embodiments, the term “reticle” can also be referred to as “mask” or “photomask.”

The lithography tool 100 further includes a projection optic system 170 at the downstream of the reticle MA and optically coupled to the reticle MA. The projection optic system 170 may include a plurality of projection lens 172. The projection optic system 170 projects the radiation beam IL outgoing from the reticle MA onto a wafer W which is coated with a light sensitive material, such as photoresist. In some embodiments, the wafer W is secured on a wafer stage WS during performing a lithography process.

Along the optical path of the radiation beam IL, the radiation beam IL passes through the beam steering system 104, the BMU 106 (and the variable attenuator 108), the shutter system 110, the zoom-axicon optic system 120, the integrator 130, the reticle blind mechanism 140, the REMA imaging optic system 150, the reticle MA, the projection optic system 170, and is incident on the wafer W. That is, the above mentioned units are optically coupled with each other.

During semiconductor manufacturing, lithography is known as one of the most key process that shrinks and projects the image from a mask (reticle) through projection lens set onto a wafer to form circuit pattern with high density. However, the lenses closest to the optical entrance and the optical exit of the optical system may be exposed to the environment air, will suffer crystallization and contamination after long using time (e.g., 3-5 years) and hence undermine the lens performance such as uniformity, transmission ratio, telecentricity, etc. Since lithography process is highly sensitive to optical behavior, unhealthy lens condition will lead to product low yield or scrap.

In FIG. 1, the optical systems of the lithography tool 100 include the zoom-axicon optic system 120, the REMA imaging optic system 150, and the projection optic system 170. With respect to the zoom-axicon optic system 120, the lenses closest to the optical entrance and the optical exit of the zoom-axicon optic system 120 may be the outmost zoom lens 122 and/or the outmost lens of the axicon 124. For example, the entrance lens of the zoom-axicon optic system 120 may be one of the zoom lenses 122 and the lenses of the axicon 124 closest to the shutter system 110, and the exit lens of the zoom-axicon optic system 120 may be another one of the zoom lenses 122 and the lenses of the axicon 124 closest to the integrator 130. Stated another way, the entrance lens of the zoom-axicon optic system 120 may be the bottommost one of the zoom lenses 122 and the lenses of the axicon 124, and the exit lens of the zoom-axicon optic system 120 may be the topmost one of the zoom lenses 122 and the lenses of the axicon 124.

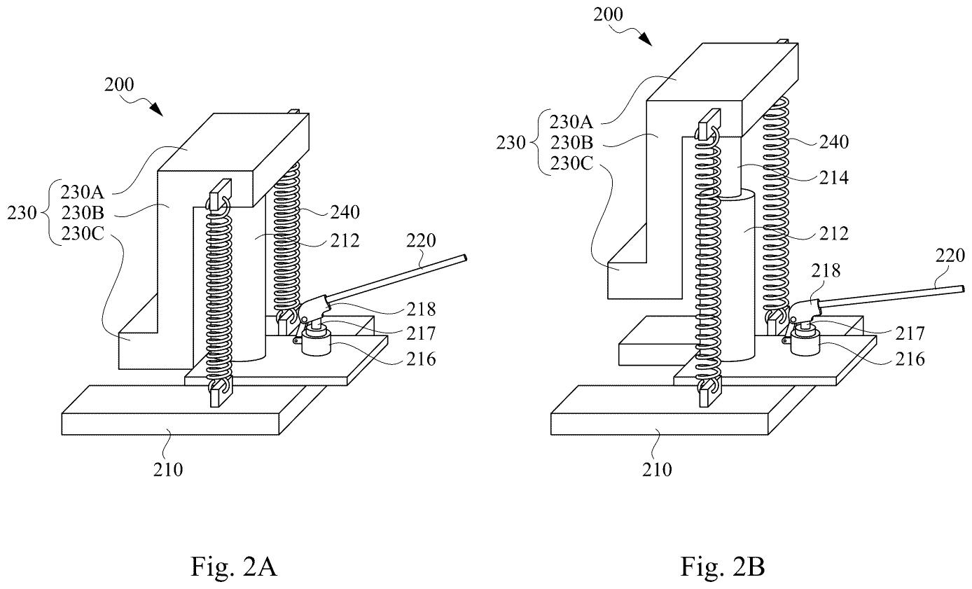

FIGS. 2A and 2B are schematic views of a lifting device in accordance with some embodiments. Shown there is a lifting device 200, in which FIGS. 2A and 2B are different conditions of the lifting device 200 during the operation. The lifting device 200 will be used to lift a REMA imaging optic system of a lithography tool, and will be discussed in more detail later.

In some embodiments, the lifting device 200 can be a hydraulic bottle jack, while the disclosure is not limited thereto. The lifting device 200 may be powered by one or more of hydraulic fluid, by compressed air or other gases, by a mechanical lever operated by a user, by an electric motor, or other sources of power or forces. The various embodiments may be used with other types of lifting devices, including for example, a multiple post vehicle lift, a farm jack, a bumper jack, a screw(s) jack, a trailer jack, a floor jack, a forklift jack, a pallet jack, a lift bag lifting device, an electric jack, jack stands, and a toe jack, and other like types of lifting devices.

The lifting device 200 includes a base 210 disposed at the bottom of the lifting device 200. The lifting device 200 includes a hydraulic cylinder 212 disposed on the base 210 and containing a piston rod 214 (see FIG. 2B) that is movable along the hydraulic cylinder 212. The lifting device 200 further includes a hydraulic cylinder 216 disposed on the base 210 and connecting to an actuator structure 218 through a piston rod 217 in the hydraulic cylinder 216. The actuator structure 218 is pivotally mounted to the base 210 and is further pivotally connected to the piston rod 217 in the hydraulic cylinder 216. A handle lever 220 can be inserted into a tubular opening of the actuator structure 218 to facilitate the pumping operation.

The lifting device 200 further includes a head 230 connected with the piston rod 214. In some embodiments, the head 230 includes a first portion 230A, a second portion 230B, and a third portion 230C, in which the second portion 230B is connected between the first portion 230A and the third portion 230C. In greater detail, the second portion 230B extends downward from the bottom surface of the first portion 230A to the top surface of the third portion 230C. Accordingly, the first portion 230A is at a level higher than the third portion 230C. In some embodiments, the first portion 230A is fixed on the piston rod 214 through the bottom surface of the first portion 230A, and thus the head 230 can be lifted by the piston rod 214.

The lifting device 200 further includes two springs 240 connecting the head 230 to the base 210. For example, first ends of the springs 240 may be connected with opposite sides of the head 230, respectively, and second ends of the springs 240 may be connected with the base 210, respectively.

FIG. 2A is a first condition where the head 230 of the lifting device 200 is at its original position. FIG. 2A is a second condition where the head 230 of the lifting device 200 is lifted to a position that is higher than the original position as shown in FIG. 2A. In operation of the lifting device 200, the handle lever 220 is pumped, for example by a user, resulting in a leverage advantage on the hydraulic cylinder 216. The piston rod in the hydraulic cylinder 216 may therefore be pumped up and down within the hydraulic cylinder 216, pumps oil from a fluid reservoir into the hydraulic cylinder 212 beneath the piston rod 214, and therefore the piston rod 214 as well as the head 230 can be lifted upwardly through hydraulic pressure.

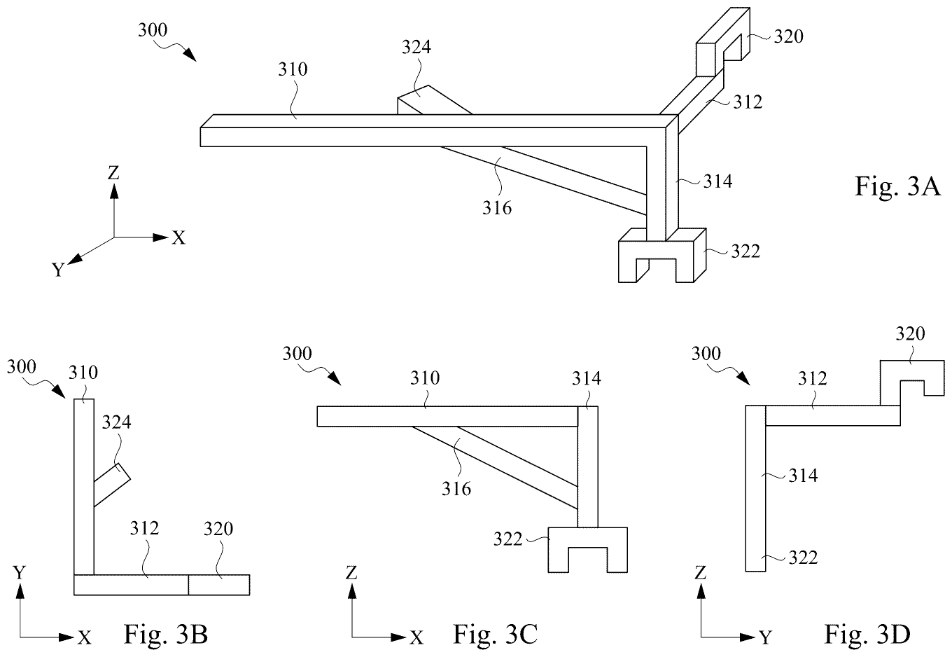

FIGS. 3A, 3B, 3C, and 3D are schematic views of a supporting bracket in accordance with some embodiments, in which FIG. 3A is a perspective view of the supporting bracket, and FIGS. 3B, 3C, and 3D are side views of the supporting bracket. Shown there is a supporting bracket 300. The supporting bracket 300 will be used to support a lifting device in an operation of a lithography tool, and will be discussed in more detail later.

The supporting bracket 300 includes strips 310, 312, and 314 connected with each other. In greater detail, the strip 310 extends along a first direction (e.g., X direction), the strip 312 extends along a second direction (e.g., Y direction) substantially perpendicular the first direction, and the strip 314 extends along a third direction (e.g., Z direction) substantially perpendicular the first direction and the second direction. Moreover, the ends of the strips 310, 312, and 314 are connected with each other.

The supporting bracket 300 further includes a strip 316 connecting the strips 310 and 314. In greater detail, the strip 316 may be in contact with a bottom surface of the strip 310 and a sidewall of the strip 314. The strip 316 will increase the rigidity of the supporting bracket 300, and will be beneficial to support an even heavier object.

The supporting bracket 300 further includes a fixing member 320 connected with the strip 312. In greater detail, the fixing member 320 is connected to an end of the strip 312 and may extend upwardly from the end of the strip 312. In some embodiments, the fixing member 320 includes a hook-shape cross-sectional profile, which is configured to facilitate the connection between the supporting bracket 300 and a lithography tool.

The supporting bracket 300 further includes a fixing member 322 connected with the strip 314. In greater detail, the fixing member 322 is connected to an end of the strip 314 and may extend downwardly from the end of the strip 314. In some embodiments, the fixing member 322 includes a U-shape cross-sectional profile, which is configured to facilitate the connection between the supporting bracket 300 and a lithography tool.

The supporting bracket 300 further includes a fixing member 324 connected with the strip 310. In greater detail, the fixing member 324 is connected to a sidewall of the strip 310 and may extend along a direction that is inclined with the lengthwise direction of the strip 310. In some embodiments, the fixing member 324 is configured to facilitate the connection between the supporting bracket 300 and a lithography tool.

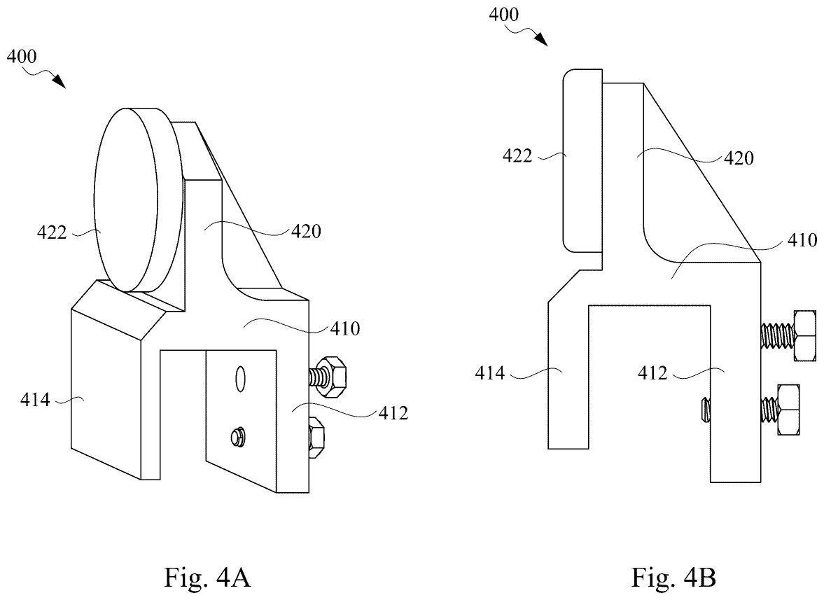

FIGS. 4A and 4B are schematic views of a rotation assisting tool in accordance with some embodiments, in which in which FIG. 4A is a perspective view of the rotation assisting tool and FIG. 4B is a side view of the rotation assisting tool. Shown there is a rotation assisting tool 400. The rotation assisting tool 400 will be used to support and facilitate the rotation of a REMA imaging optic system in a lithography tool, and will be discussed in more detail later.

The rotation assisting tool 400 include a plate 410, a plate 412, and a plate 414. In greater detail, the plate 412 and the plate 414 are connected with opposite ends of the plate 410 and may extend downwardly from the bottom surface of the plate 410. The plates 410, 412, and 414 collectively form a substantially U-shape cross-sectional profile, which is configured to facilitate the connection between the rotation assisting tool 400 and a lithography tool. In some embodiments, the plate 412 may include one or more holes that allow screws to penetrate through.

The rotation assisting tool 400 further includes a plate 420 connected with the plate 410. In greater detail, the plate 420 extends upwardly from the top surface of the plate 410. The rotation assisting tool 400 further includes a wheel 422 fixed on the plate 420, which is configured to facilitate the rotation of a REMA imaging optic system in a lithography tool.

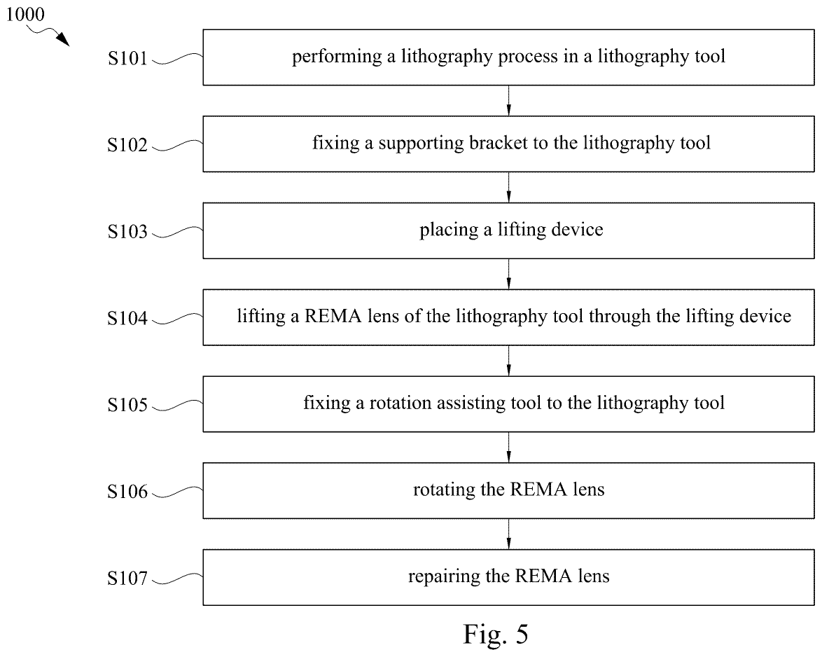

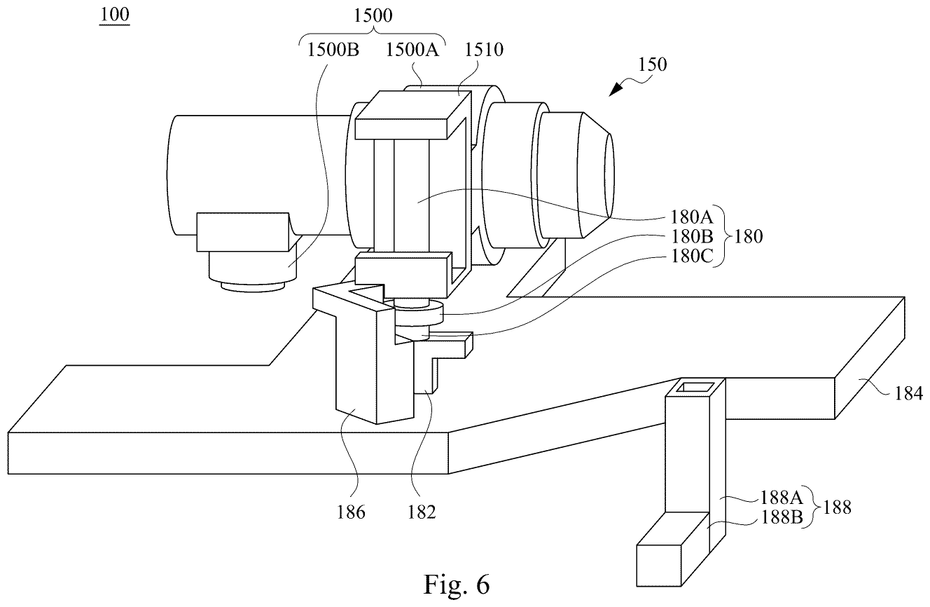

FIG. 5 is a method of operating a lithography tool in accordance with some embodiments. FIGS. 6 to 11 are schematic views of a lithography tool at various stages of operating a lithography tool in accordance with some embodiments. FIG. 5 shows a method 1000 of operating the lithography tool 100 as discussed in FIG. 1, and the method 1000 of FIG. 5 will be discussed in conjunction with FIGS. 6 to 11 and FIGS. 2A to 2B, 3A to 3D, and 4A to 4B as discussed above. It is noted that, for the sake of brevity, only the REMA imaging optic system 150 of FIG. 1 is illustrated in FIGS. 6 to 11. Although the method 1000 is described as a series of acts, it will be appreciated that these acts are not limiting in that the order of the acts can be altered in other embodiments. In other embodiments, some acts that are illustrated and/or described may be omitted in whole or in part.

Reference is made to FIGS. 5 and 6. The method 1000 starts from operation S101 by performing a lithography process in a lithography tool. For example, as discussed in FIG. 1, a wafer W is transferred to the lithography tool 100 and is secured on a wafer stage WS. Then, a lithography process may be performed on the wafer W using the lithography tool 100.

In FIG. 6, the REMA imaging optic system 150 includes a REMA lens 1500 and a connection member 1510 connected with the REMA lens 1500. In some embodiments, the REMA lens 1500 includes a first portion 1500A (or a horizontal portion) and a second portion 1500B (or a vertical portion) connecting with each other. The first portion 1500A has a lengthwise direction extends horizontally, and the second portion 1500B has a lengthwise direction extends vertically, in which the second portion 1500B may extend downwardly from one end of the first portion 1500A. In some embodiments, the first portion 1500A can be regarded as a portion of the REMA imaging optic system 150 that contains the first set of condenser lenses 152 and the mirror 156 (see FIG. 1), and the second portion 1500B can be regarded as a portion of the REMA imaging optic system 150 that contains the second set of condenser lenses 154. The lithography tool 100 further includes a connection member 1510 connected with a sidewall of the first portion 1500A of the REMA lens 1500.

The lithography tool 100 further includes a shaft 180 fixed on the connection member 1510 of the REMA imaging optic system 150. In some embodiments, the shaft 180 may include a top portion 180A, a middle portion 180B, and a bottom portion 180C, in which the middle portion 180B is between the top portion 180A and the bottom portion 180C. In some embodiments, the top portion 180A of the shaft 180 is fixed on the connection member 1510 and may penetrate through the connection member 1510. In some embodiments, the middle portion 180B and the bottom portion 180C of the shaft 180 are below the bottom surface of the connection member 1510. In some embodiments, the top portion 180A, the middle portion 180B, and the bottom portion 180C each may include a cylindrical shape. That is, the top portion 180A, the middle portion 180B, and the bottom portion 180C each may include a circular top cross-sectional profile. In some embodiments, the middle portion 180B is wider than the top portion 180A and the bottom portion 180C. That is, a diameter of the middle portion 180B is larger than the diameters of the top portion 180A and the bottom portion 180C. In some embodiments, the shaft 180 is rotatable. Since the shaft 180 is connected to the REMA lens 1500 through the connection member 1510, the REMA lens 1500 can be rotated together with the shaft 180.

The lithography tool 100 further includes a lifting frame 182 connected with the bottom portion 180C of the shaft 180. In some embodiments, the lifting frame 182 can be fixed on the bottom portion 180C of the shaft 180, for example, by screw(s). In some embodiments, the lifting frame 182 may include an L-shape profile. For example, the lifting frame 182 may include a horizontal portion and a vertical portion extending downward from one end of the horizontal portion.

The lithography tool 100 further includes a working table 184, a supporting frame 186 disposed on the working table 184, and a fixing bracket 188 connected with the working table 184. In some embodiments, the bottom portion 180C of the shaft 180 may penetrate through the working table 184. In some embodiments, the supporting frame 186 is in contact with the bottom surface of the connection member 1510, and is used to support the connection member 1510, as well as the REMA lens 150, during performing the lithography process. In some embodiments, the fixing bracket 188 may include an L-shape profile. That is, the fixing bracket 188 may include a strip 188A and a strip 188B connected with each other. In some embodiments, the strip 188A may be a hollow structure, and thus an opening may be present at the top surface of the strip 188A of the fixing bracket 188.

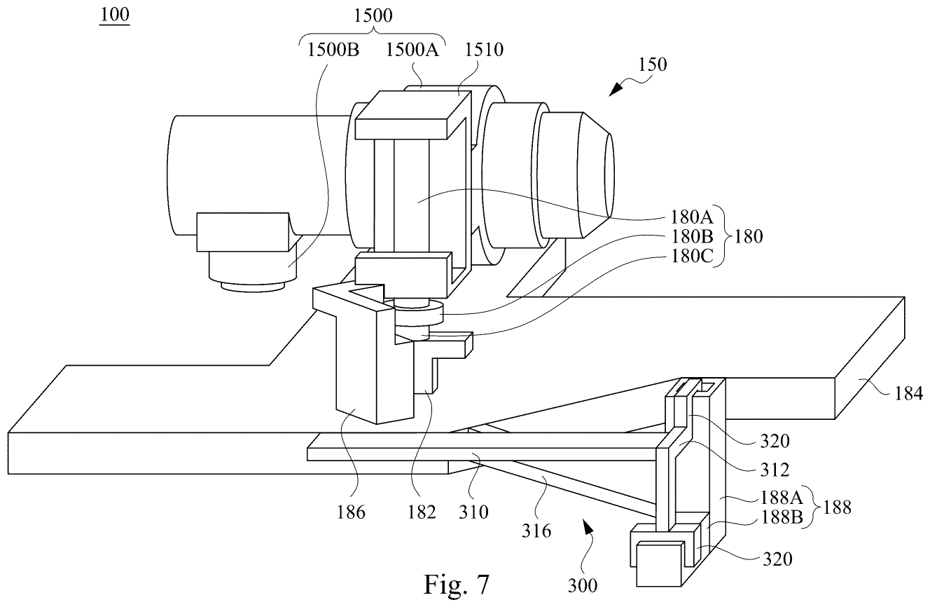

Reference is made to FIGS. 5 and 7. The method 1000 proceeds to operation S102 by fixing a supporting bracket to the lithography tool. In greater detail, the supporting bracket 300 as discussed in FIGS. 3A to 3D will be used in the operation S102 described herein. In some embodiments, the supporting bracket 300 is designed such that the supporting bracket 300 can be stably fixed on the working table 184 and the fixing bracket 188 of the lithography tool 100.

In some embodiments, the fixing member 320 on the strip 312 of the supporting bracket 300 is hooked up at the strip 188A of the fixing bracket 188. For example, the hook structure of the fixing member 320 may be hang on the strip 188A of the fixing bracket 188 by inserting a portion of fixing member 320 in the opening of the strip 188A of the fixing bracket 188. On the other hand, the fixing member 322 on the strip 314 of the supporting bracket 300 is mounted on the strip 188B of the fixing bracket 188. For example, the U-shape fixing member 322 can cross the strip 188B of the fixing bracket 188, such that the fixing member 322 covers and in contact with three sides of the strip 188B of the fixing bracket 188. Moreover, the fixing member 324 is fixed on the working table 184, for example, by screw(s).

After the supporting bracket 300 is fixed on the working table 184 and the fixing bracket 188 of the lithography tool 100, the top surfaces of the strips 310 and 312 of the supporting bracket 300 may be substantially coplanar with the top surface of the working table 184. That is, the top surfaces of the strips 310 and 312 of the supporting bracket 300 may be at a same level with the top surface of the working table 184.

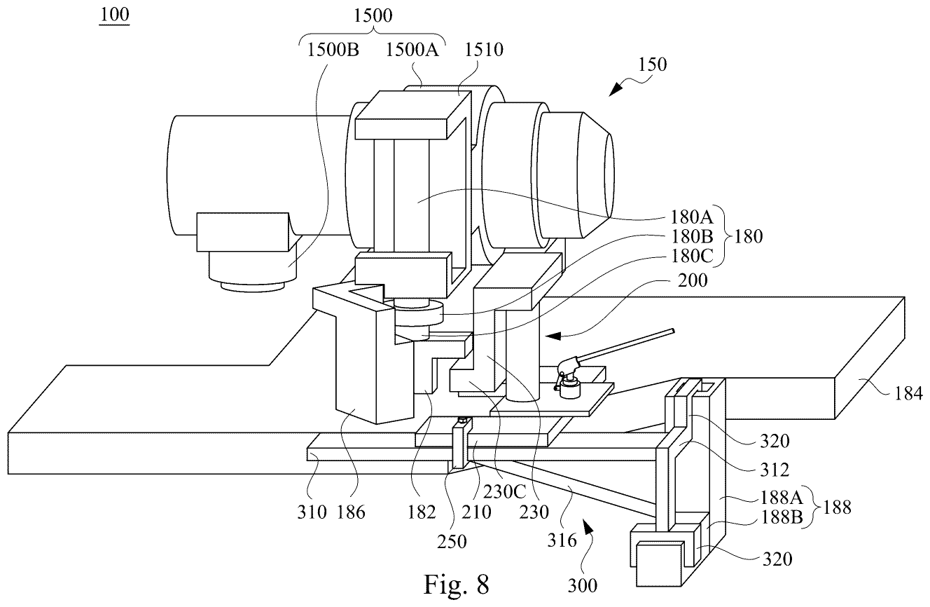

Reference is made to FIGS. 5 and 8. The method 1000 proceeds to operation S103 by placing a lifting device. In greater detail, the lifting device 200 as discussed in FIGS. 2A to 2B will be used in the operation S103 described herein. In some embodiments, the lifting device 200 is placed on the working table 184 and the supporting bracket 300, such that the base 210 of the lifting device 200 is in contact with both the working table 184 and the supporting bracket 300. Moreover, the orientation of the lifting device 200 is adjusted such that the third portion 230C of the head 230 of the lifting device 200 is in contact with the bottom surface of the lifting frame 182. It is noted that the springs 240 of the lifting device 200 are not illustrated in FIG. 8 for brevity.

In some embodiments, the lifting device 200 can also be fixed on the supporting bracket 300 through a clamp 250. In some embodiments, the clamp 250 may clamp the base 210 of the lifting device 200 with the strip 310 of the supporting bracket 300. The present of the supporting bracket 300 makes it more flexible to adjust the position of the lifting device 200, and the lifting device 200 can also be stably fixed on the supporting bracket 300 through the clamp 250.

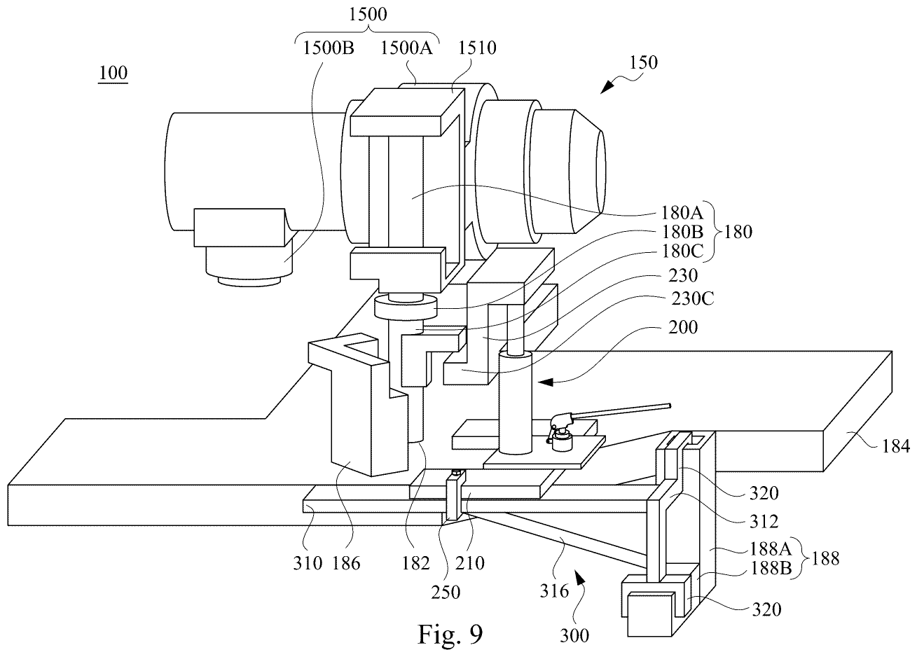

Reference is made to FIGS. 5 and 9. The method 1000 proceeds to operation S104 by lifting a REMA lens of the lithography tool through the lifting device. In some embodiments, the REMA lens 1500 is lifted by the lifting device 200, such that the REMA lens 1500 is moved from a first position (see FIG. 8) to a second position that is higher than the first position (see FIG. 9). In greater detail, by lifting the head 230 of the lifting device 200, the head 230 of the lifting device 200 may push the lifting frame 182 that is connected to the shaft 180, and the shaft 180 as well as the REMA lens 1500 will be lifted together with the lifting frame 182. In some embodiments, when the REMA lens 1500 is at the first position (see FIGS. 6 to 8), the REMA lens 1500 can be regarded as being at a processing status where a lithography process can be performed. On the other hand, when the REMA lens 1500 is at the second position (see FIG. 9), the REMA lens 1500 can be regarded as being at an operation status where a repairing operation can be performed.

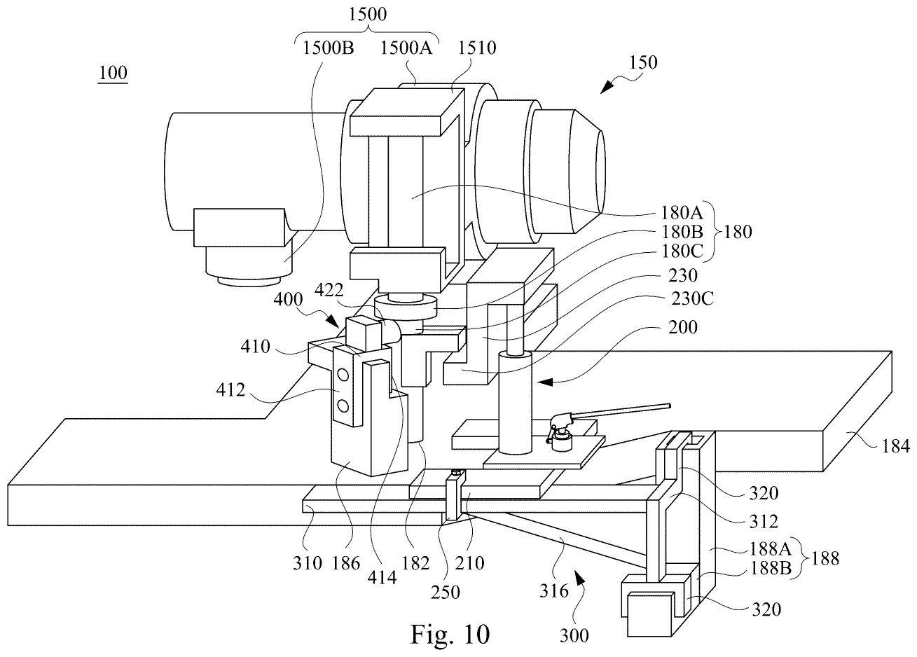

Reference is made to FIGS. 5 and 10. The method 1000 proceeds to operation S105 by fixing a rotation assisting tool to the lithography tool. In greater detail, the rotation assisting tool 400 as discussed in FIGS. 4A to 4B will be used in the operation S105 described herein. In some embodiments, after the REMA lens 1500 is lifted, the connection member 1510 is vertically spaced apart from the supporting frame 186, therefore creating a space between the supporting frame 186 and the connection member 1510. Then, the rotation assisting tool 400 is fixed on the supporting frame 186. In some embodiments, the rotation assisting tool 400 may cross the supporting frame 186, and may be fixed on the supporting frame 186, for example, by screw(s). In greater detail, the plates 412 and 414 of the rotation assisting tool 400 may be in contact with sidewalls of the supporting frame 186, and the plate 410 of the rotation assisting tool 400 is in contact with the top surface of the supporting frame 186. Moreover, the wheel 422 of the rotation assisting tool 400 is in contact with the bottom surface of the middle portion 180B of the shaft 180, such that that middle portion 180B of the shaft 180 can slide along the wheel 422 of the rotation assisting tool 400 during the rotation of the shaft 180.

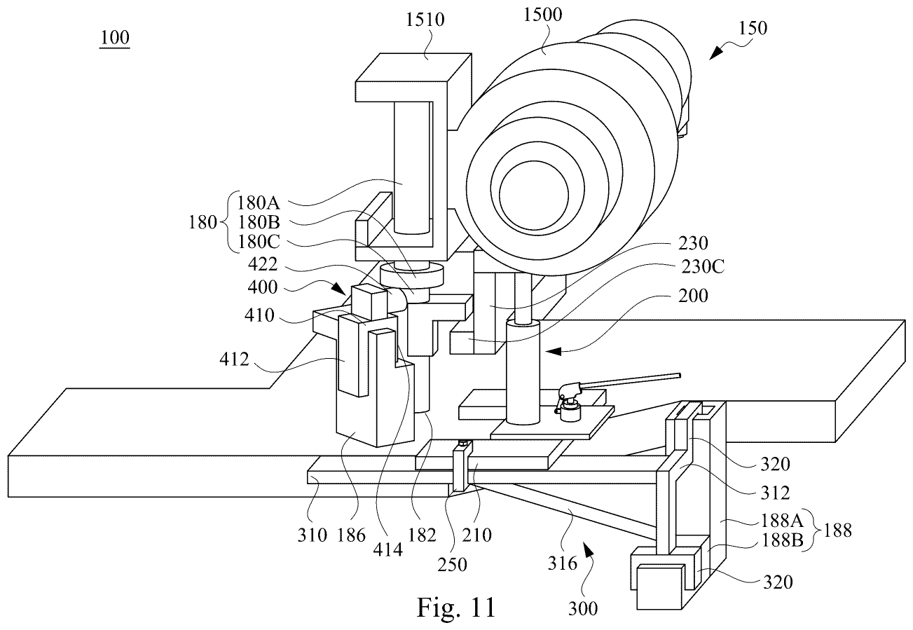

Reference is made to FIGS. 5 and 11. The method 1000 proceeds to operation S106 by rotating the REMA lens. In greater detail, the REMA lens 1500 of the REMA imaging optic system 150 is rotated, such that the aperture of the REMA lens 1500 may face outwardly, for example, to the user. In some embodiments, the REMA lens 1500 can be rotated through the shaft 180 as discussed above. During the rotation of the shaft 180, the wheel 422 of the rotation assisting tool 400 can not only support the middle portion 180B of the shaft 180, but can also maintain a smooth rotation of the shaft 180.

The method 1000 proceeds to operation S107 by repairing the REMA lens. In some embodiments, the REMA lens 1500 can be repaired by, for example, replacing the set of the condenser lenses 152 with a new set of the condenser lenses 152. However, the disclosure is not limited thereto, in other embodiments, the operation S107 can be performed by repairing other optical elements in the REMA lens 1500.

In some embodiments, when the operation of repairing the REMA lens 1500 is complete, the REMA lens 1500 can be rotated back to its original orientation. Then, the rotation assisting tool 400, the lifting device 200, and the supporting bracket 300 can be detached from the lithography tool 100, and the REMA lens 1500 can be lowered back to the first position as shown in FIG. 6.

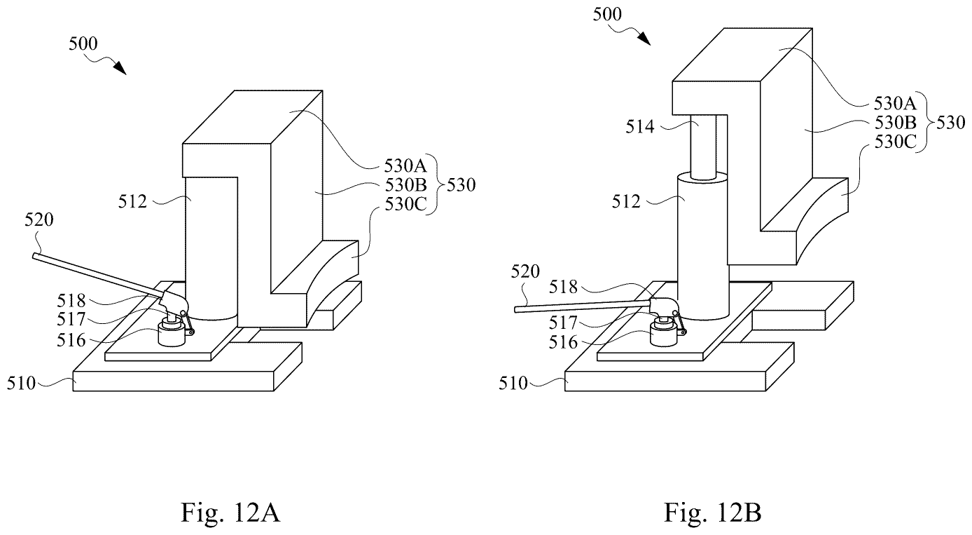

FIGS. 12A and 12B are schematic views of a lifting device in accordance with some embodiments. Shown there is a lifting device 500, in which FIGS. 12A and 12B are different conditions of the lifting device 500 during the operation. The lifting device 500 will be used to lift a REMA imaging optic system of a lithography tool, and will be discussed in more detail later. It is noted that the lifting device 500 may be similar to the lifting device 200 as discussed in FIGS. 2A and 2B, and thus relevant details may not be repeated for brevity.

The lifting device 500 includes a base 510 disposed at the bottom of the lifting device 500. The lifting device 500 includes a hydraulic cylinder 512 disposed on the base 510 and containing a piston rod 514 (see FIG. 12B) that is movable along the hydraulic cylinder 512. The lifting device 500 further includes a hydraulic cylinder 516 disposed on the base 510 and connecting to an actuator structure 518 through a piston rod (not shown) in the hydraulic cylinder 516. The actuator structure 518 is pivotally mounted to the base 510 and is further pivotally connected to the piston rod in the hydraulic cylinder 516. A handle lever 520 can be inserted into a tubular opening of the actuator structure 518 to facilitate the pumping operation.

The lifting device 500 further includes a head 530 connected with the piston rod 514. In some embodiments, the head 530 includes a first portion 530A, a second portion 530B, and a third portion 530C, in which the second portion 530B is connected between the first portion 530A and the third portion 530C. In greater detail, the second portion 530B extends downward from the bottom surface of the first portion 530A to the top surface of the third portion 530C. Accordingly, the first portion 530A is at a level higher than the third portion 530C. In some embodiments, the first portion 530A is fixed on the piston rod 514 through the bottom surface of the first portion 530A, and thus the head 530 can be lifted by the piston rod 514. In some embodiments, the third portion 530C may include a curved sidewall, the curved sidewall may be beneficial to connect the lifting device 500 with a shaft in a lithography tool, and will be discussed in more detail later.

FIG. 12A is a first condition where the head 530 of the lifting device 500 is at its original position. FIG. 12A is a second condition where the head 530 of the lifting device 500 is lifted to a position that is higher than the original position as shown in FIG. 12A. In operation of the lifting device 500, the handle lever 520 is pumped, for example by a user, resulting in a leverage advantage on the hydraulic cylinder 516. The piston rod in the hydraulic cylinder 516 may therefore be pumped up and down within the hydraulic cylinder 516, pumps oil from a fluid reservoir into the hydraulic cylinder 512 beneath the piston rod 514, and therefore the piston rod 514 as well as the head 530 can be lifted upwardly through hydraulic pressure.

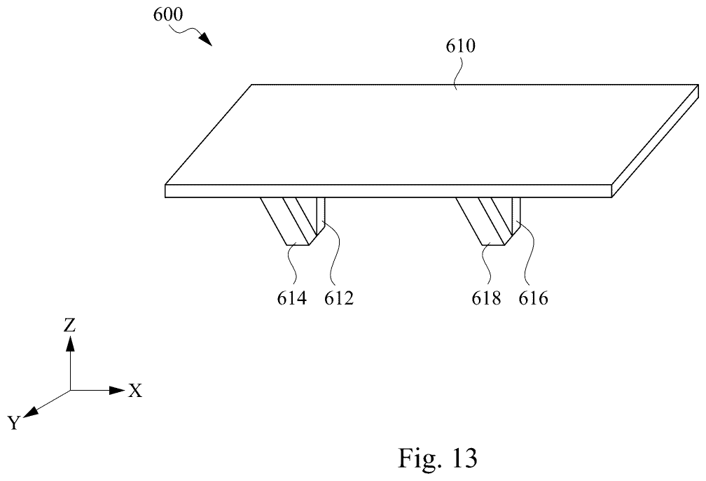

FIG. 13 is a schematic view of a supporting bracket in accordance with some embodiments. Shown there is a supporting bracket 600. The supporting bracket 600 will be used to support a lifting device in an operation of a lithography tool, and will be discussed in more detail later. The supporting bracket 600 includes a platform 610 and strips 612, 614, 616, and 618 connected to the platform 610. In greater detail, one end of the strip 612 is in contact with the bottom surface of the platform 610, and the strip 614 is in contact with another end of the strip 612 and the bottom surface of the platform 610. Similarly, one end of the strip 616 is in contact with the bottom surface of the platform 610, and the strip 618 is in contact with another end of the strip 616 and the bottom surface of the platform 610. In some embodiments, the strips 612 and 616 may extend along a vertically direction (e.g., X direction).

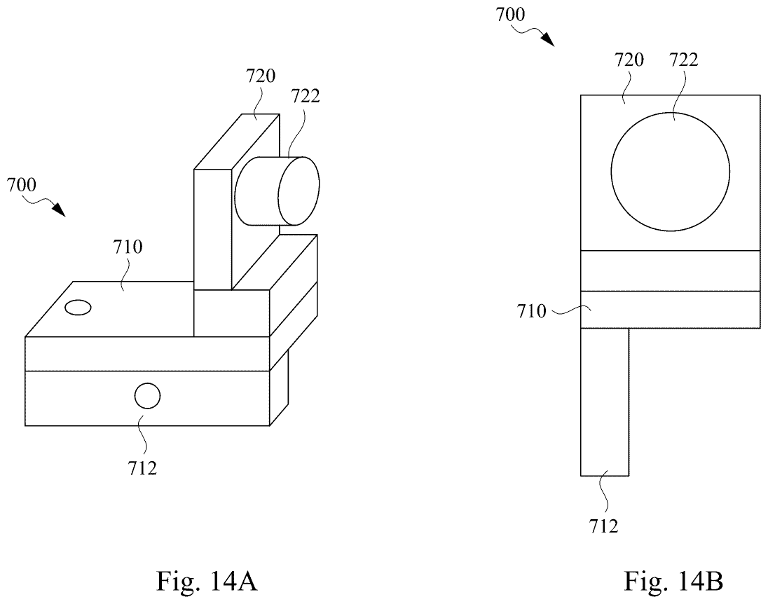

FIGS. 14A and 14B are schematic views of a rotation assisting tool in accordance with some embodiments, in which in which FIG. 14A is a perspective view of the rotation assisting tool and FIG. 14B is a side view of the rotation assisting tool. Shown there is a rotation assisting tool 700. The rotation assisting tool 700 will be used to support and facilitate the rotation of a REMA imaging optic system in a lithography tool, and will be discussed in more detail later.

The rotation assisting tool 700 include a plate 710 and a plate 712. In greater detail, the plate 712 is connected with one end of the plate 710 and may extend downwardly from the bottom surface of the plate 710. The plates 710 and 712 collectively form a substantially L-shape cross-sectional profile, which is configured to facilitate the connection between the rotation assisting tool 700 and a lithography tool.

The rotation assisting tool 700 further includes a plate 720 connected with the plate 710. In greater detail, the plate 720 extends upwardly from the top surface of the plate 710. The rotation assisting tool 700 further includes a wheel 722 fixed on the plate 720, which is configured to facilitate the rotation of a REMA imaging optic system in a lithography tool.

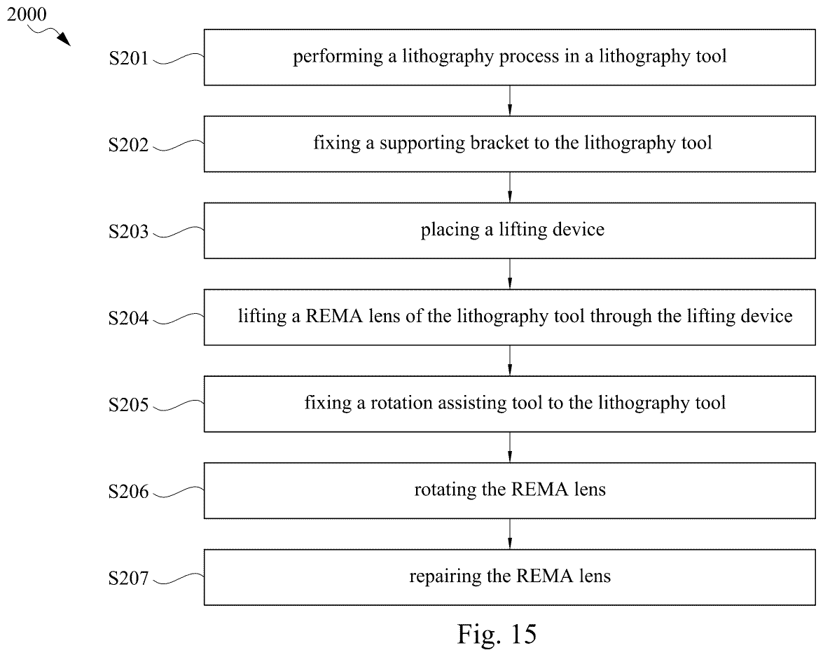

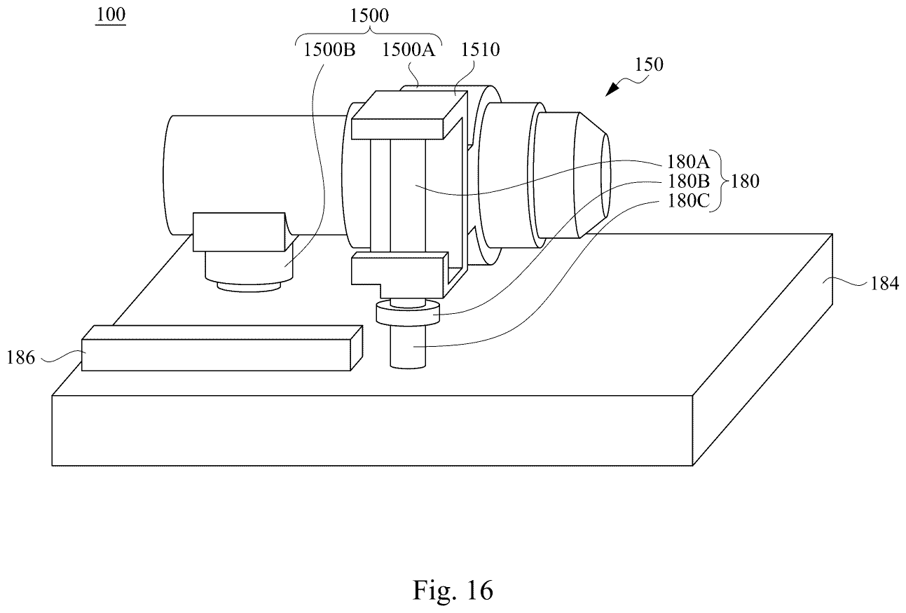

FIG. 15 is a method of operating a lithography tool in accordance with some embodiments. FIGS. 16 to 21 are schematic views of a lithography tool at various stages of operating a lithography tool in accordance with some embodiments. FIG. 15 shows a method 2000 of operating the lithography tool 100 as discussed in FIG. 1, and the method 2000 of FIG. 15 will be discussed in conjunction with FIGS. 16 to 21 and FIGS. 12A to 12B, 13, and 14A to 14B as discussed above. It is noted that, for the sake of brevity, only the REMA imaging optic system 150 of FIG. 1 is illustrated in FIGS. 16 to 21. Although the method 2000 is described as a series of acts, it will be appreciated that these acts are not limiting in that the order of the acts can be altered in other embodiments. In other embodiments, some acts that are illustrated and/or described may be omitted in whole or in part.

Reference is made to FIGS. 15 and 16. The method 2000 starts from operation S201 by performing a lithography process in a lithography tool. For example, as discussed in FIG. 1, a wafer W is transferred to the lithography tool 100 and is secured on a wafer stage WS. Then, a lithography process may be performed on the wafer W using the lithography tool 100.

In FIG. 16, the REMA imaging optic system 150 includes a REMA lens 1500 and connection member 1510 connected with the REMA lens 1500. In some embodiments, the REMA lens 1500 includes a first portion 1500A (or a horizontal portion) and a second portion 1500B (or a vertical portion) connecting with each other. The first portion 1500A has a lengthwise direction extends horizontally, and the second portion 1500B has a lengthwise direction extends vertically, in which the second portion 1500B may extend downwardly from one end of the first portion 1500A. In some embodiments, the first portion 1500A can be regarded as a portion of the REMA imaging optic system 150 that contains the first set of condenser lenses 152 and the mirror 156 (see FIG. 1), and the second portion 1500B can be regarded as a portion of the REMA imaging optic system 150 that contains the second set of condenser lenses 154. The lithography tool 100 further includes a connection member 1510 connected with a sidewall of the first portion 1500A of the REMA lens 1500.

The lithography tool 100 further includes a shaft 180 fixed on the connection member 1510 of the REMA imaging optic system 150. In some embodiments, the shaft 180 may include a top portion 180A, a middle portion 180B, and a bottom portion 180C, in which the middle portion 180B is between the top portion 180A and the bottom portion 180C. In some embodiments, the top portion 180A of the shaft 180 is fixed on the connection member 1510 and may penetrate through the connection member 1510. In some embodiments, the middle portion 180B and the bottom portion 180C of the shaft 180 are below the bottom surface of the connection member 1510. In some embodiments, the top portion 180A, the middle portion 180B, and the bottom portion 180C each may include a cylindrical shape. That is, the top portion 180A, the middle portion 180B, and the bottom portion 180C each may include a circular top cross-sectional profile. In some embodiments, the middle portion 180B is wider than the top portion 180A and the bottom portion 180C. That is, a diameter of the middle portion 180B is larger than the diameters of the top portion 180A and the bottom portion 180C. In some embodiments, the shaft 180 is rotatable. Since the shaft 180 is connected to the REMA lens 1500 through the connection member 1510, the REMA lens 1500 can be rotated together with the shaft 180.

The lithography tool 100 further includes a working table 184 and a supporting frame 186 disposed on the working table 184. In some embodiments, the bottom portion 180C of the shaft 180 may penetrate through the working table 184.

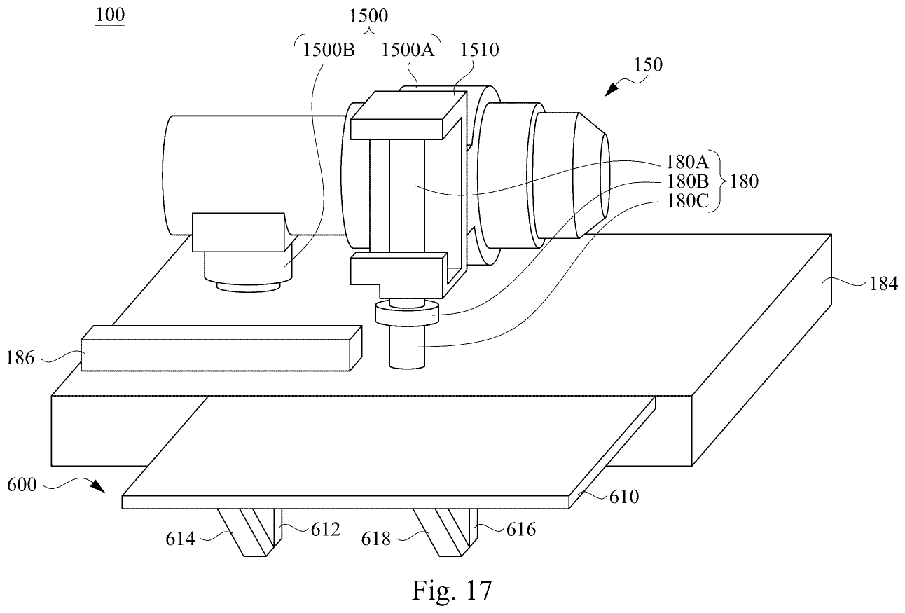

Reference is made to FIGS. 15 and 17. The method 2000 proceeds to operation S202 by fixing a supporting bracket to the lithography tool. In greater detail, the supporting bracket 600 as discussed in FIG. 13 will be used in the operation S202 described herein. In some embodiments, the supporting bracket 600 is designed such that the supporting bracket 600 can be stably fixed on the working table 184 of the lithography tool 100.

In some embodiments, strips 612 and 616 of the supporting bracket 600 can be fixed on the working table 184 of the lithography tool 100, for example, by screw(s) or the suitable connection method. After the supporting bracket 600 is fixed on the working table 184 of the lithography tool 100, the top surface of the platform 610 of the supporting bracket 600 may be substantially coplanar with the top surface of the working table 184. That is, the top surface of the platform 610 of the supporting bracket 600 may be at a same level with the top surface of the working table 184.

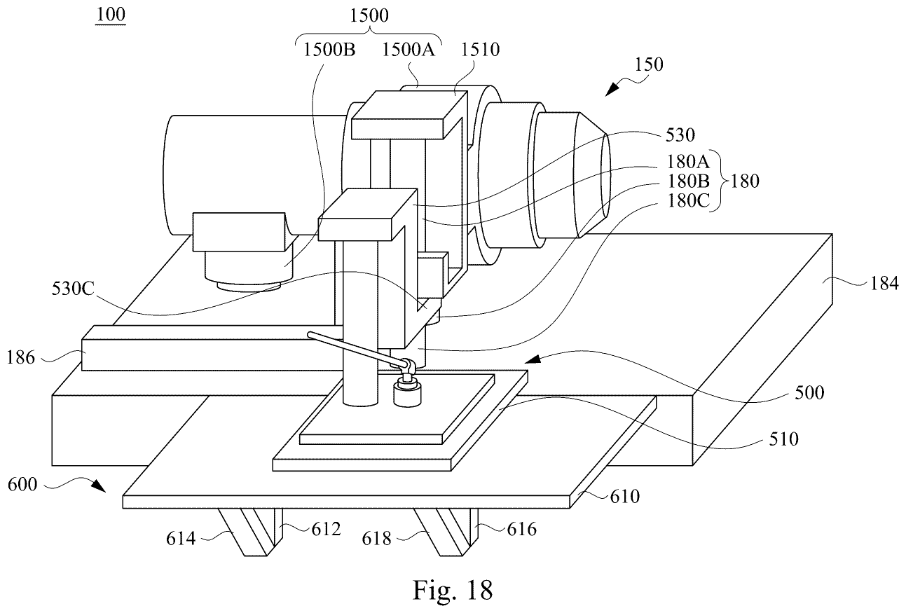

Reference is made to FIGS. 15 and 18. The method 2000 proceeds to operation S203 by placing a lifting device. In greater detail, the lifting device 500 as discussed in FIGS. 12A to 12B will be used in the operation S203 described herein. In some embodiments, the lifting device 500 is placed on the working table 184 and the supporting bracket 600, such that the base 510 of the lifting device 500 is in contact with both the working table 184 and the supporting bracket 600. Moreover, the orientation of the lifting device 500 is adjusted such that the third portion 530C of the head 530 of the lifting device 500 is in contact with the bottom surface of the connection member 1510. As discussed in FIGS. 12A and 12B, the third portion 530C of the head 530 of the lifting device 500 may include a curved surface, and the lifting device 500 can be positioned such that the curved surface of the third portion 530C of the head 530 is in contact with the curved sidewall of the top portion 180A of the shaft 180. The present of the supporting bracket 600 makes it more flexible to adjust the position of the lifting device 500.

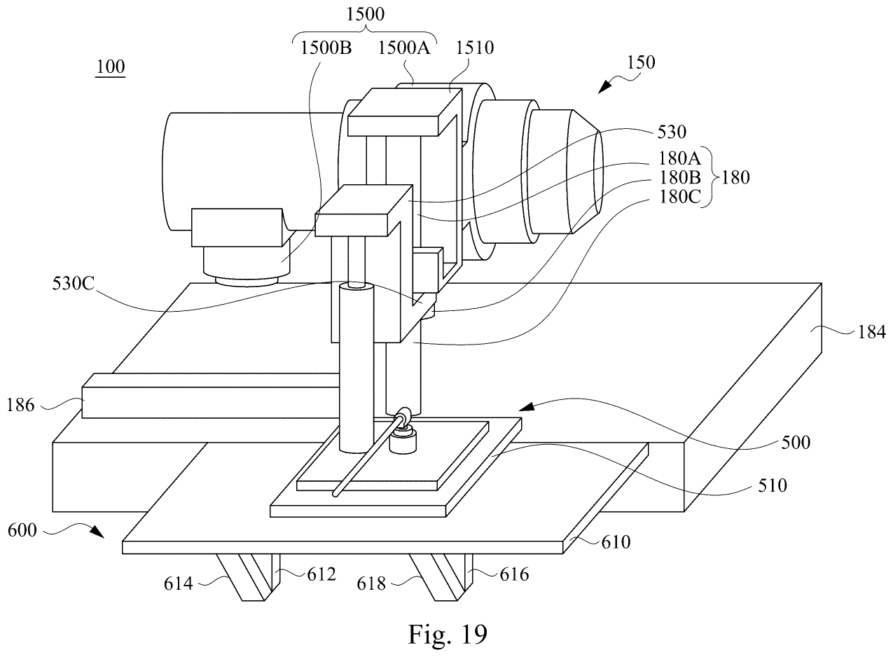

Reference is made to FIGS. 15 and 19. The method 2000 proceeds to operation S204 by lifting a REMA lens of the lithography tool through the lifting device. In some embodiments, the REMA lens 1500 is lifted by the lifting device 500, such that the REMA lens 1500 is moved from a first position (see FIG. 18) to a second position that is higher than the first position (see FIG. 19). In greater detail, by lifting the head 530 of the lifting device 500, the head 530 of the lifting device 500 may push the connection member 1510 that is connected to the shaft 180, and the shaft 180 as well as the REMA lens 1500 will be lifted together with the connection member 1510.

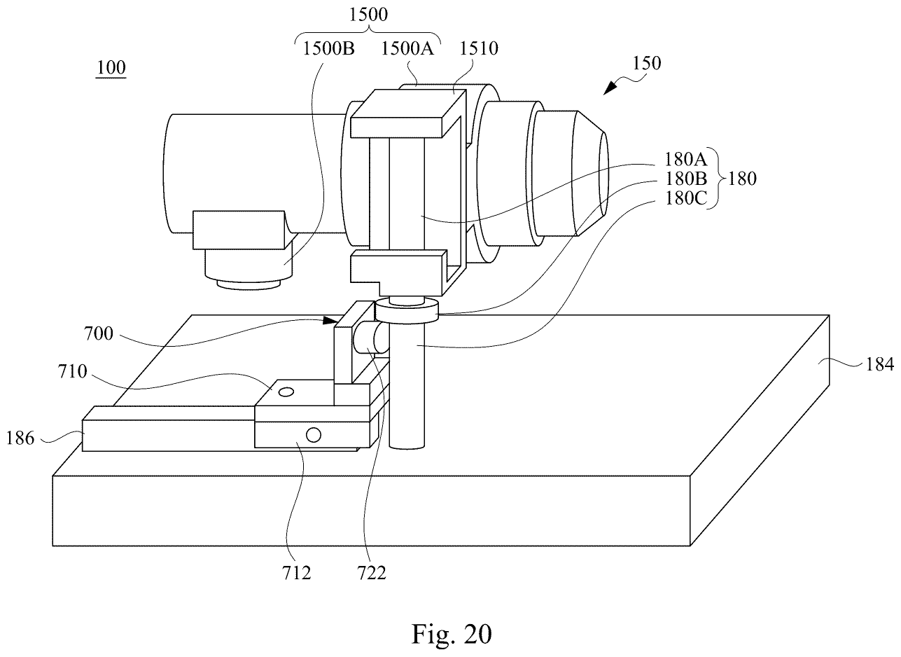

Reference is made to FIGS. 15 and 20. The method 2000 proceeds to operation S205 by fixing a rotation assisting tool to the lithography tool. In greater detail, the rotation assisting tool 700 as discussed in FIGS. 14A to 14B will be used in the operation S205 described herein. In some embodiments, after the REMA lens 1500 is lifted, the connection member 1510 is vertically spaced apart from the supporting frame 186, therefore creating a space between the supporting frame 186 and the connection member 1510. Then, the rotation assisting tool 700 is fixed on the supporting frame 186. In greater detail, the plate 712 of the rotation assisting tool 700 may be in contact with sidewall of the supporting frame 186, and the plate 710 of the rotation assisting tool 700 is in contact with the top surface of the supporting frame 186. That is, the rotation assisting tool 700 is in contact with at least two sides of the supporting frame 186. In some embodiments, the rotation assisting tool 700 may be fixed on the supporting frame 186, for example, by screw(s). Moreover, the wheel 722 of the rotation assisting tool 700 is in contact with the bottom surface of the middle portion 180B of the shaft 180. The supporting bracket 600 and the lifting device 500 are omitted in FIG. 19 to clearly show the structure of the rotation assisting tool 700. It is understood that the supporting bracket 600 and the lifting device 500 may still be present during the operation S205.

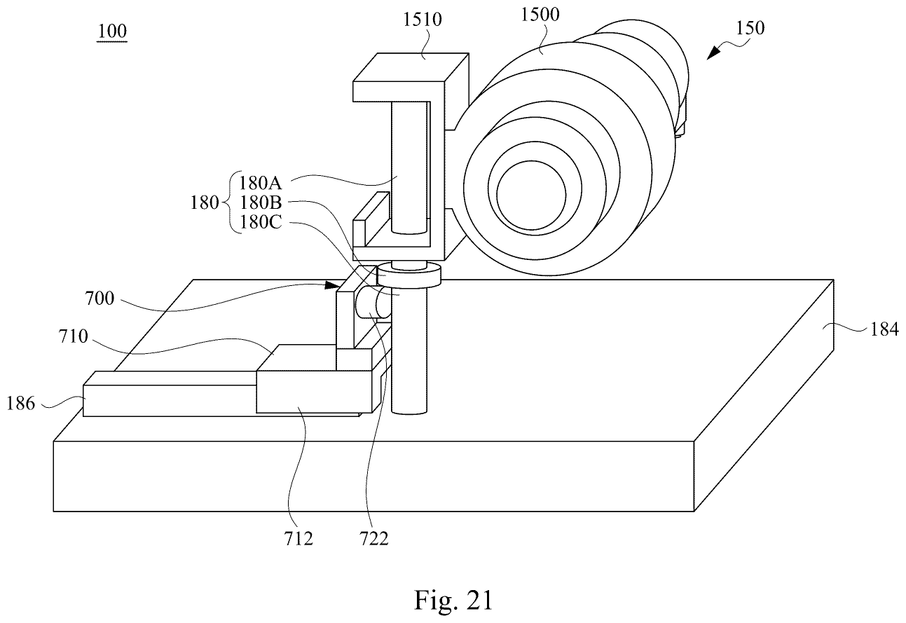

Reference is made to FIGS. 15 and 21. The method 2000 proceeds to operation S206 by rotating the REMA lens. In greater detail, the REMA lens 1500 of the REMA imaging optic system 150 is rotated, such that the aperture of the REMA lens 1500 may face outwardly, for example, to the user. In some embodiments, the REMA lens 1500 can be rotated through the shaft 180 as discussed above. During the rotation of the shaft 180, the wheel 722 of the rotation assisting tool 700 can not only support the middle portion 180B of the shaft 180, but can also maintain a smooth rotation of the shaft 180. The supporting bracket 600 and the lifting device 500 are omitted in FIG. 19 to clearly show the structure of the rotation assisting tool 700. It is understood that the supporting bracket 600 and the lifting device 500 may still be present during the operation S205.

The method 2000 proceeds to operation S207 by repairing the REMA lens. In some embodiments, the REMA lens 1500 can be repaired by, for example, replacing the set of the condenser lenses 152 with a new set of the condenser lenses 152. However, the disclosure is not limited thereto, in other embodiments, the operation S207 can be performed by repairing other optical elements in the REMA lens 1500.

In some embodiments, when the operation of repairing the REMA lens 1500 is complete, the REMA lens 1500 can be rotated back to its original orientation. Then, the rotation assisting tool 700, the lifting device 500, and the supporting bracket 600 can be detached from the lithography tool 100, and the REMA lens 1500 can be lowered back to the first position as shown in FIG. 16.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method of a lithography tool. A supporting frame is fixed on a working table of the lithography tool, and a lifting device is placed on the supporting frame and the working table. An optical element (e.g., a REMA lens) of the lithography tool can be lifted using the lifting device without using the lifting mechanism (e.g., a gas cylinder) integrated in the lithography tool, and will be beneficial to prolong the lifetime of the lifting mechanism. Moreover, the supporting frame allows the lifting device to be stably fixed to the lithography tool, and makes it flexible to adjust the position of the lifting device. Embodiments of the present disclosure also provide a method by fixing a rotation assisting tool to the lithography tool, such that a wheel of the rotation assisting tool is in contact with a shaft connected to the optical element. The rotation assisting tool can not only support the shaft, but can also maintain a smooth rotation of the shaft, which will improve the structure stability of the lithography tool.

In some embodiments of the present disclosure, a method includes fixing a supporting bracket to a working table in a lithography tool; placing a lifting device on the supporting bracket; lifting an optical element in lithography tool, using the lifting device, from a first level to a second level higher than the first level; rotating the optical element through a shaft connected with the optical element; and repairing the optical element.

In some embodiments, the method further includes prior to rotating the optical element, fixing a rotation assisting tool to the lithography tool, wherein the rotation assisting tool comprises a wheel in contact with a bottom surface of a portion of the shaft.

In some embodiments, fixing the rotation assisting tool to the lithography tool is performed after lifting the optical element.

In some embodiments, the method further includes clamping the lifting device on the supporting bracket with a clamp.

In some embodiments, the lifting the optical element comprises pushing, using the lifting device, a lifting frame connected to the shaft.

In some embodiments, the method further includes detaching the lifting device and the supporting bracket from the lithography tool after repairing the optical element.

In some embodiments, a base of the lifting device is in contact with the working table and the supporting bracket.

In some embodiments, the optical element is a reticle masking (REMA) lens.

In some embodiments, the lifting device is a hydraulic bottle jack.

In some embodiments of the present disclosure, a method includes lifting an optical element in a lithography tool from a first level to a second level higher than the first level; fixing a rotation assisting tool to the lithography tool, wherein the rotation assisting tool comprises a wheel in contact with a bottom surface of a portion of a shaft connected to the optical element; rotating the optical element through the shaft, wherein the portion of the shaft slides along the wheel of the rotation assisting tool during rotating the optical element; and repairing the optical element.

In some embodiments, the rotation assisting tool is fixed on a supporting frame in the lithography tool, and wherein the rotation assisting tool is in contact with at least two sides of the supporting frame.

In some embodiments, the rotation assisting tool is fixed on the supporting frame by screw.

In some embodiments, the method further includes fixing a supporting bracket to a working table in the lithography tool; and placing a lifting device on the supporting bracket, wherein lifting the optical element is performed using the lifting device.

In some embodiments, the method further includes detaching the rotation assisting tool from the lithography tool after repairing the optical element.

In some embodiments, repairing the optical element comprises replacing a lens in the optical element with a new lens.

In some embodiments of the present disclosure, a lithography tool includes a working table. An optical element is over the working table. A shaft is connected with the optical element, wherein the shaft is rotatable. A rotation assisting tool is fixed on the working table, wherein the rotation assisting tool comprises a wheel in contact with a bottom surface of a portion of the shaft.

In some embodiments, the rotation assisting tool is detachable from the working table.

In some embodiments, the portion of the shaft slides along the wheel of the rotation assisting tool during rotating the optical element.

In some embodiments, the lithography tool further includes a supporting frame on the working table, wherein the rotation assisting tool is fixed on the supporting frame, and wherein the rotation assisting tool is in contact with at least two sides of the supporting frame.

In some embodiments, the rotation assisting tool is fixed on the supporting frame by screw.

In some embodiments, the shaft comprises a bottom portion, a top portion, and a middle portion between the bottom portion and the top portion, wherein the wheel is in contact with the middle portion.

In some embodiments of the present disclosure, a lithography tool includes a working table. A supporting bracket is connected to the working table. An optical element is over the working table. A lifting device is disposed on the working table and the supporting bracket, wherein the lifting device is configured to lifting the optical element from a first level to a second level higher than the first level.

In some embodiments, the lifting device is fixed on the supporting bracket with a clamp.

In some embodiments, the lifting device is detachable from the working table and the supporting bracket.

In some embodiments, a top surface of the supporting bracket is level with a top surface of the working table.

In some embodiments, the optical element is a reticle masking (REMA) lens.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
fixing a supporting bracket to a working table in a lithography tool;
placing a lifting device on the supporting bracket;
lifting an optical element in lithography tool, using the lifting device, from a first level to a second level higher than the first level;
rotating the optical element through a shaft connected with the optical element; and
repairing the optical element.

2. The method of claim 1, further comprising prior to rotating the optical element, fixing a rotation assisting tool to the lithography tool, wherein the rotation assisting tool comprises a wheel in contact with a bottom surface of a portion of the shaft.

3. The method of claim 2, wherein fixing the rotation assisting tool to the lithography tool is performed after lifting the optical element.

4. The method of claim 1, further comprising clamping the lifting device on the supporting bracket with a clamp.

5. The method of claim 1, wherein the lifting the optical element comprises pushing, using the lifting device, a lifting frame connected to the shaft.

6. The method of claim 1, further comprising detaching the lifting device and the supporting bracket from the lithography tool after repairing the optical element.

7. The method of claim 1, wherein a base of the lifting device is in contact with the working table and the supporting bracket.

8. The method of claim 1, wherein the optical element is a reticle masking (REMA) lens.

9. The method of claim 1, wherein the lifting device is a hydraulic bottle jack.

10. A lithography tool, comprising:
a working table;
an optical element over the working table;
a shaft connected with the optical element, wherein the shaft is rotatable; and
a rotation assisting tool fixed on the working table, wherein the rotation assisting tool comprises a wheel in contact with a bottom surface of a portion of the shaft.

11. The lithography tool of claim 10, wherein the rotation assisting tool is detachable from the working table.

12. The lithography tool of claim 10, wherein the portion of the shaft slides along the wheel of the rotation assisting tool during rotating the optical element.

13. The lithography tool of claim 10, further comprising a supporting frame on the working table, wherein the rotation assisting tool is fixed on the supporting frame, and wherein the rotation assisting tool is in contact with at least two sides of the supporting frame.

14. The lithography tool of claim 13, wherein the rotation assisting tool is fixed on the supporting frame by screw.

15. The lithography tool of claim 10, wherein the shaft comprises a bottom portion, a top portion, and a middle portion between the bottom portion and the top portion, wherein the wheel is in contact with the middle portion.

16. A lithography tool, comprising:
a working table;
a supporting bracket connected to the working table;
an optical element over the working table; and
a lifting device disposed on the working table and the supporting bracket, wherein the lifting device is configured to lifting the optical element from a first level to a second level higher than the first level.

17. The lithography tool of claim 16, wherein the lifting device is fixed on the supporting bracket with a clamp.

18. The lithography tool of claim 16, wherein the lifting device is detachable from the working table and the supporting bracket.

19. The lithography tool of claim 16, wherein a top surface of the supporting bracket is level with a top surface of the working table.

20. The lithography tool of claim 16, wherein the optical element is a reticle masking (REMA) lens.
